(19) United States
(12) Patent Application Publication
(10) Pub. No.: US 2006/0030161 A1
(43) Pub. Date: Feb. 9, 2006

(54) Film forming method

(75) Inventors: Hideaki Machida, Yamanashi (JP); Yoshio Ohshita, Aichi (JP); Atsushi Ogura, Tokyo (JP); Masato Ishikawa, Yamanashi (JP); Takeshi Kada, Yamanashi (JP)

Correspondence Address: OBLON, SPIVAK, MCCLELLAND, MAIER & NEUSTADT, P.C., 1940 DUKE STREET, ALEXANDRIA, VA, 22314, US

(73) Assignee: Tri Chemical Laboratories Inc., Kitatsuru-Gun (JP)

(21) Appl. No.: 11/117,341

(22) Filed: Apr. 29, 2005

(30) Foreign Application Priority Data
Aug. 6, 2004 (JP) 2004-231619

(51) Int. Cl. H01L 21/31

(52) U.S. Cl. 438/758

(57) ABSTRACT

A technique capable of forming an NiSi film having excellent characteristics, which TiSi₂ or CoSi₂ produced thus far is not able to assume, without damaging a substrate is provided.

A film forming material for forming a nickel silicide film or a Nickel film is provided, wherein an Ni source of said film is Ni(PF₃)₄.

### BACKGROUND OF THE INVENTION

The present invention relates more particularly to semiconductor elements.

At the present moment, the progress in the semiconductor field is remarkable, and LSIs are being converted into ULSIs. And, so as to improve a signal processing speed, forming a fine-grained structure is being developed. Also, copper having a low resistance is selected as wiring conductor materials, the spacing between wiring conductors is filled with a material having a very low dielectric constant, and a trend of extremely thinning a film goes up steadily. A conversion of a gate oxide film, which is currently made of SiO₂, into a metal oxide film such as HfO₂ has been also studied.

However, even if the above-mentioned idea is adopted, the formation of a fine-grained structure leads to extremely shallow diffusion layers at source-drain regions. Therefore, the resistance is increased, so it is difficult to improve the signal processing speed. In recent years, not only the contact at the source-drain region, but also the resistance of the gate electrode has been perceived as problems, and it has been long wanted to develop new materials.

In order to overcome such problems, metal silicide such as TiSi₂ and CoSi₂ have been studied.

[Patent document 1] JP-P1994-204173A

However, it is predicted that TiSi₂ or CoSi₂ has a limit in performance improvement in the future.

In view of such a limitation, the present inventor et al. consider that NiSi must be introduced for the future semiconductor elements.

It is considered that the sputtering technique allows this NiSi thin film to be prepared easily.

The sputtering, however, damages the semiconductor elements physically. Moreover, NiSi may make a reactive consumption of Si, being a base substrate, at a high temperature to turn into NiSi₂. Moreover, there is a limit in uniformity of a film having a large area.

For that reason, a technique of forming NiSi films at a low temperature, for example, with a CVD (chemical vapor deposition) process has been waited.

Also, it is predicted that the nickel film will hold an important place as an electrode with a development in micro-machines of recent years.

### SUMMARY OF THE INVENTION

Thus, the task to be solved by the present invention is to provide a technology of forming silicide (NiSi) films or nickel films with the CVD process, which is capable of solving the above-mentioned problems.

In the course of going aggressively with a research for solving the above-mentioned problems, the present inventor et al. noticed that it was very important to specify what should be employed as configuration materials of the nickel films or the silicide films.

And, as a result of further having continued the research, it has been found out that Ni(PF₃)₄ is employed very preferably as an Ni source. Moreover, in addition hereto, it has been also found out that in a case of employing chemical compounds represented with SiₓH₍₂ₓ₊₂₎, where X is an integer of 1 or more, more preferable silicide films can be produced.

The present invention has been achieved based upon such knowledge.

That is, in order to solve the above-mentioned problems, a method is applied of forming a film containing Ni, comprising:

an Ni source supply step of supplying Ni(PF₃)₄ as an Ni source of said film; and

a decomposition step of decomposing Ni(PF₃)₄ supplied in said Ni source supply step.

Also, a method is applied of forming a nickel silicide film containing Ni and Si, comprising:

an Ni source supply step of supplying Ni(PF₃)₄ as an Ni source of said film;

an Si source supply step of supplying SiₓH₍₂ₓ₊₂₎, where X is an integer of 1 or more, as an Si source of said film;

a decomposition step of decomposing Ni(PF₃)₄ supplied in said Ni source supply step; and

a decomposition step of decomposing SiₓH₍₂ₓ₊₂₎ supplied in said Si source supply step.

The present invention provides a film obtained in said film forming methods.

Moreover, the present invention provides a film forming material for forming a film having Ni, wherein an Ni source of said film is Ni(PF₃)₄.

Also, the present invention provides a film forming material for forming a nickel silicide film having Ni and Si, wherein an Ni source of said film is Ni(PF₃)₄, and wherein an Si source of said film is SiₓH₍₂ₓ₊₂₎, where X is an integer of 1 or more.

Moreover, the present invention provides a semiconductor element comprising a film having Ni, wherein Ni(PF₃)₄ is supplied as an Ni source of said film, and wherein said film is configured by decomposing said supplied Ni(PF₃)₄.

In particular, the present invention provides a semiconductor element comprising a nickel silicide film having Ni and Si, wherein Ni(PF₃)₄ is supplied as an Ni source of said film, wherein SiₓH₍₂ₓ₊₂₎, where X is an integer of 1 or more, is supplied as an Si source of said film, and wherein said film is configured by decomposing said supplied Ni(PF₃)₄ and SiₓH₍₂ₓ₊₂₎.

Said Ni(PF₃)₄ is a reaction product between one or more chemical compounds selected from the group consisting of [C₅H₅]₂Ni, [(CH₃)C₅H₄]₂Ni, [(C₂H₅)C₅H₄]₂Ni, [(i-C₃H₇)C₅H₄]₂Ni and [(n-C₄H₉)C₅H₄]₂Ni, and PF₃. Its purity is 99% or more.

PF₃ is produced in forming said film, that is, in decomposing said Ni(PF₃)₄. Employing this PF₃ for synthesis of Ni(PF₃)₄ is very convenient.

Accordingly, the present invention further comprises a reaction step of reacting PF₃, which is a decomposition product to be produced at the time that Ni(PF₃)₄ for forming a film is decomposed, with one or more chemical compounds selected from the group consisting of [C₅H₅]₂Ni, [(CH₃)C₅H₄]₂Ni, [(C₂H₅)C₅H₄]₂Ni, [(i-C₃H₇)C₅H₄]₂Ni and [(n-C₄H₉)C₅H₄]₂Ni, and employs Ni(PF₃)₄ obtained in said reaction step for film forming.

Said SiₓH₍₂ₓ₊₂₎ is, particularly, one or more chemical compounds selected from the group consisting of SiH₄, Si₂H₆, and Si₃H₈.

In the present invention, the film forming materials are decomposed simultaneously or separately. The decomposition is made by employing at least one of the techniques selected from the group consisting of heat, light, and a hot filament.

The film forming method of the present invention further comprises a reducing agent supply step of supplying a reducing agent (particularly, hydrogen).

The film forming material of the present invention is, particularly, a material for forming a film with the CVD process. Moreover, it is a material for forming the silicide film in the semiconductor elements such as MOSFETs.

In accordance with the present invention, the nickel film or the nickel silicide film is obtained with the CVD process of hardly damaging the substrate. Moreover, there is no fear that NiSi₂ is formed through the chemical reaction with Si of the base substrate.

The semiconductor element provided with the film formed by employing Ni(PF₃)₄ was excellent as compared with the semiconductor element provided with the film formed by employing TiSi₂ or CoSi₂.

### BRIEF DESCRIPTION OF THE DRAWING

This and other objects, features and advantages of the present invention will become apparent upon a reading of the following detailed description and a drawing, in which:

FIG. 1 is a schematic diagram illustrating a chemical vapor deposition (CVD) apparatus.

### DESCRIPTION OF THE EMBODIMENTS

The film forming method of the present invention is a method of forming the nickel film (or the nickel silicide film). It comprises an Ni(PF₃)₄ supply step of supplying Ni(PF₃)₄ as an Ni source of said film, and a decomposition step of decomposing Ni(PF₃)₄ supplied in said Ni(PF₃)₄ supply step. It further comprises a reducing agent supply step of supplying a reducing agent (particularly, hydrogen). Also, it further comprises an SiₓH₍₂ₓ₊₂₎ (where X is an integer of 1 or more, preferably an integer of 10 or less.) supply step of supplying SiₓH₍₂ₓ₊₂₎ as an Si source of the nickel silicide film, and a decomposition step of decomposing SiₓH₍₂ₓ₊₂₎ supplied in said SiₓH₍₂ₓ₊₂₎ supply step. The film forming method of the present invention is, particularly, a method using the CVD process. In the present invention, the film forming materials are decomposed simultaneously or separately. The decomposition is made by employing at least one of the techniques selected from the group consisting of heat, light, and a hot filament.

The film of the present invention is a film obtained by said film forming methods.

The film forming material of the present invention is a film forming material for forming the nickel film (or the nickel silicide film). An Ni source of said film is Ni(PF₃)₄. An Si source of said nickel silicide film is SiₓH₍₂ₓ₊₂₎, where X is an integer of 1 or more.

Said Ni(PF₃)₄ is, particularly, a chemical compound produced by reacting one or more chemical compounds selected from the group consisting of [C₅H₅]₂Ni, [(CH₃) C₅H₄]₂Ni, [(C₂H₅)C₅H₄]₂Ni, [(i-C₃H₇)C₅H₄]₂Ni and [(n-C₄H₉)C₅H₄]₂Ni with PF₃. Its purity is 99% or more. PF₃ is produced at the time of decomposing Ni(PF₃)₄ in forming the film of the present invention. Accordingly, PF₃ produced by this decomposition can be employed for said PF₃.

The chemical compound, which is preferable as said SiₓH₍₂ₓ₊₂₎, is one or more chemical compounds selected from the group consisting of SiH₄, Si₂H₆, and Si₃H₈.

The film forming material of the present invention is, particularly, a material for forming a film with the CVD process. Moreover, it is a material for forming the silicide film in the semiconductor elements such as MOSFETs.

The element of the present invention comprises the nickel film or the nickel silicide film formed in the above-mentioned film forming methods. Or, the element of the present invention comprises the nickel film or the nickel silicide film formed by employing the above-mentioned film forming materials.

Specific embodiments will be described below.

### EMBODIMENT 1

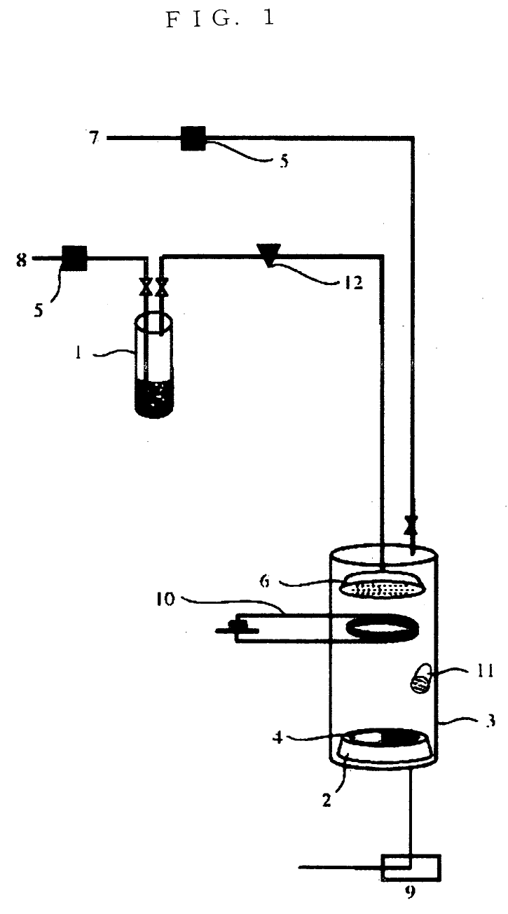

FIG. 1 is a schematic diagram illustrating a chemical vapor deposition (CVD) apparatus. Referring to FIG. 1, 1 represents a raw material container, 2 represents a heater, 3 represents a decomposition reactor, 4 represents an Si (semiconductor) substrate, 5 represents a gas flow controller, 6 represents an a gas outlet of source gas, 7 represents a leading line of silane such as SiH₄, Si₂H₆ and Si₃H₈, and H₂, 8 represents a leading line of carrier gas, 9 represents an exhaust pipe and concurrently a recovery apparatus/reactor of PF₃, 10 represents a ring-shape hot filament, 11 represents a photo-irradiation device, and 12 represents a needle valve for regulating pressure within the raw material container.

Ni(PF₃)₄ was placed in the container 1, and was maintained at 20° C. The decomposition reactor 3 was evacuated in vacuum. The substrate 4 was heated at 150-350° C.

The needle valve 12 was released and the vaporized Ni(PF₃)₄ was introduced into the decomposition reactor 3 via a conduit. Mixed gas of SiH₄ and H₂ were introduced at a rate of 20 ml/min as reaction gas at the time of introducing Ni(PF₃)₄ into the decomposition reactor 3.

As a result, the film was formed on the substrate 4.

When this film was investigated with an XPS (X-ray photoelectron spectroscopy), existence of Ni and Si was confirmed. And, as a result of investigating it with an X-ray, it was confirmed that the film was an NiSi film.

This NiSi film was preferred for the next generation semiconductor elements.

Additionally, Ni(PF₃)₄ employed in this embodiment is one obtained by reacting [C₅H₅]₂Ni with PF₃. A check with a gas chromatograph demonstrated that its purity was 99% or more.

A similar process was performed by employing Ni(PF₃)₄ obtained by reacting [(CH₃)C₅H₄]₂Ni with PF₃, Ni(PF₃)₄ obtained by reacting [(C₂H₅)C₅H₄]₂Ni with PF₃, Ni(PF₃)₄ obtained by reacting [(i-C₃H₇)C₅H₄]₂Ni with PF₃, and Ni(PF₃)₄ obtained by reacting [(n-C₄H₉)C₅H₄]₂Ni with PF₃ instead of Ni(PF₃)₄ obtained by reacting [C₅H₅]₂Ni with PF₃, respectively.

The obtained silicide films are ones similar to the above-mentioned silicide film.

### EMBODIMENT 2

The embodiment 2 was carried out similarly to the embodiment 1 with the exception that the reaction gas Si₂H₆ was employed instead of SiH₄.

As a result, the similar NiSi film was formed. This NiSi film was preferred for the next generation semiconductor elements.

### EMBODIMENT 3

The embodiment 3 was carried out similarly to the embodiment 1 with the exception that the reaction gas Si₃H₈ was employed instead of SiH₄.

As a result, the similar NiSi film was formed. This NiSi film was preferred for the next generation semiconductor elements.

### EMBODIMENTS 4 AND 5

In the embodiment 1, the decomposition of the chemical compound was made with the heating means. The embodiments 4 and 5 were carried out similarly to the embodiment 1 with the exception that the means of the photo-irradiation or the laser-irradiation was employed instead of this heating means.

As a result, the similar NiSi film was formed. This NiSi film was preferred for the next generation semiconductor elements.

### EMBODIMENT 6

In the embodiment 1, the decomposition of the chemical compound was made with the heating means.

The embodiment 6 was carried out similarly to the embodiment 1 with exception that the decomposition was made with Ni(PF₃)₄ brought into contact with the hot filament 10 heated at 800° C. or more on the way to the Si substrate 4 instead of this decomposition heating means.

As a result, the similar NiSi film was formed. This NiSi film was preferred for the next generation semiconductor elements.

### EMBODIMENT 7

Ni(PF₃)₄ is decomposed in the film forming. Ni is deposited on the Si substrate 4, thus allowing the film to be produced. PF₃ is recovered into the recovery apparatus/reactor 9. And, PF₃ recovered by the recovery apparatus/reactor 9 was reacted with [C₅H₅]₂Ni. This reaction product was purified so that its purity became 99% or more to obtain the reproduced Ni(PF₃)₄. The embodiment 7 was carried out similarly to the embodiment 1 with the exception that this reproduced Ni(PF₃)₄ was employed instead of Ni(PF₃)₄ employed in the embodiment 1.

As a result, the similar NiSi film was formed. This NiSi film was preferred for the next generation semiconductor elements.

### EMBODIMENT 8

The embodiment 8 was carried out similarly to the embodiment 7 with the exception that [(CH₃)C₅H₄]₂Ni was employed to obtain the reproduced Ni(PF₃)₄ instead of [C₅H₅]₂Ni.

As a result, the similar NiSi film was formed. This NiSi film was preferred for the next generation semiconductor elements.

### EMBODIMENT 9

The embodiment 9 was carried out similarly to the embodiment 7 with the exception that [(C₂H₅)C₅H₄]₂Ni was employed to obtain the reproduced Ni(PF₃)₄ instead of [C₅H₅]₂Ni.

As result, the similar NiSi film was formed. This NiSi film was preferred for the next generation semiconductor elements.

### EMBODIMENT 10

The embodiment 10 was carried out similarly to the embodiment 7 with the exception that [(i-C₃H₇)C₅H₄]₂Ni was employed to obtain the reproduced Ni(PF₃)₄ instead of [C₅H₅]₂Ni.

As a result, the similar NiSi film was formed. This NiSi film was preferred for the next generation semiconductor elements.

### EMBODIMENT 11

The embodiment 11 was carried out similarly to the embodiment 7 with the exception that [(n-C₄H₉)C₅H₄]₂Ni was employed to obtain the reproduced Ni(PF₃)₄ instead of [C₅H₅]₂Ni.

As a result, the similar NiSi film was formed. This NiSi film was preferred for the next generation semiconductor elements.

### EMBODIMENT 12

The chemical vapor deposit apparatus of FIG. 1 was employed. The embodiment 12 was carried out similarly to the embodiment 1 with the exception that H₂ was introduced at a rate of 20 ml/min as reaction gas. That is, SiH₄ was not employed.

And, the film was formed on the substrate 4.

When this film was investigated with the XPS, existence of Ni was confirmed. Also, as a result of investigating it with an X-ray, it was confirmed that it was an Ni film.

Particularly, the present invention can be usefully applied in the semiconductor fields.

What is claimed is:

1. A method of forming a film containing Ni, comprising:
an Ni source supply step of supplying Ni(PF₃)₄ as an Ni source of said film; and
a decomposition step of decomposing Ni(PF₃)₄ supplied in said Ni source supply step.

2. The method of forming the film as claimed in claim 1, wherein said Ni(PF₃)₄ is a reaction product between one or more chemical compounds selected from the group consisting of [C₅H₅]₂Ni, [(CH₃)C₅H₄]₂Ni, [(C₂H₅)C₅H₄]₂Ni, [(i-C₃H₇)C₅H₄]₂Ni and [(n-C₄H₉)C₅H₄]₂Ni, and PF₃, and yet a reaction product of which purity is 99% or more.

3. The method of forming the film as claimed in claim 1, comprising a reaction step of reacting PF₃ with one or more chemical compounds selected from the group consisting of [C₅H₅]₂Ni, [(CH₃)C₅H₄]₂Ni, [(C₂H₅)C₅H₄]₂Ni, [(i-C₃H₇)C₅H₄]₂Ni and [(n-C₄H₉)C₅H₄]₂Ni, said PF₃ being produced at the time that said Ni(PF₃)₄ is decomposed, wherein said Ni source supply step has a step of supplying Ni(PF₃)₄ obtained in said reaction step.

4. The method of forming the film as claimed in claim 1, wherein the film is formed with a CVD process.

5. The method of forming the film as claimed in claim 1, wherein said decomposition is a decomposition employing at least one technique selected from the group consisting of heat, light, and a hot filament.

6. The method of forming the film as claimed in claim 1, further comprising a reducing agent supply step of supplying a reducing agent.

7. The method of forming the film as claimed in claim 6, wherein said reducing agent is hydrogen.

8. A method of forming a film containing Ni and Si, wherein said film is a nickel silicide film, comprising:
an Ni source supply step of supplying Ni(PF₃)₄ as an Ni source of said film;
a decomposition step of decomposing Ni(PF₃)₄ supplied in said Ni source supply step;
an Si source supply step of supplying SiₓH₍₂ₓ₊₂₎, where X is an integer of 1 or more, as an Si source of said film; and
a decomposition step of decomposing SiₓH₍₂ₓ₊₂₎ supplied in said Si source supply step.

9. The method of forming the film as claimed in claim 8, wherein said Ni(PF₃)₄ is a reaction product between one or more chemical compounds selected from the group consisting of [C₅H₅]₂Ni, [(CH₃)C₅H₄]₂Ni, [(C₂H₅)C₅H₄]₂Ni, [(i-C₃H₇) C₅H₄]₂Ni and [(n-C₄H₉)C₅H₄]₂Ni, and PF₃, and yet a reaction product of which purity is 99% or more.

10. The method of forming the film as claimed in claim 8, comprising a reaction step of reacting PF₃ with one or more chemical compounds selected from the group consisting of [C₅H₅]₂Ni, [(CH₃)C₅H₄]₂Ni, [(C₂H₅) C₅H₄]₂Ni, [(i-C₃H₇)C₅H₄]₂Ni and [(n-C₄H₉)C₅H₄]₂Ni, said PF₃ being produced at the time that said Ni(PF₃)₄ is decomposed, wherein said Ni source supply step has a step of supplying Ni(PF₃)₄ obtained in said reaction step.

11. The method of forming the film as claimed in claim 8, wherein the film is formed with a CVD process.

12. The method of forming the film as claimed in claim 8, wherein said decomposition is a decomposition employing at least one technique selected from the group consisting of heat, light, and a hot filament.

13. The method of forming the film as claimed in claim 8, further comprising a reducing agent supply step of supplying a reducing agent.

14. The method of forming the film as claimed in claim 13, wherein said reducing agent is hydrogen.

15. The method of forming the film as claimed in claim 8, wherein said SiₓH₍₂ₓ₊₂₎ is one or more chemical compounds selected from the group consisting of SiH₄, Si₂H₆, and Si₃H₈.

16. The method of forming the film as claimed in claim 8, wherein film forming materials are decomposed simultaneously or separately.
